(19) United States
(12) Patent Application Publication
(10) Pub. No.: US 2023/0309237 A1
(43) Pub. Date: Sep. 28, 2023

(54) PACKAGING STRUCTURE, LENS MODULE, AND ELECTRONIC DEVICE

(71) Applicant: TRIPLE WIN TECHNOLOGY(SHENZHEN) CO.LTD., Shenzhen (CN)

(72) Inventor: HSIN-YEN HSU, New Taipei (TW)

(21) Appl. No.: 17/993,484

(22) Filed: Nov. 23, 2022

(30) Foreign Application Priority Data
Mar. 22, 2022 (CN) 202210286263.8

(51) Int. Cl. H05K 1/18; H05K 1/14; H01L 27/146

(52) U.S. Cl. CPC H05K 1/189; H05K 1/142; H01L 27/14625; H01L 27/14618; H01L 27/14636; H05K 2201/058; H05K 2201/2009; H05K 2201/10121; H05K 2201/10151

(57) ABSTRACT

A packaging structure includes a flexible circuit board, an image sensor, a reinforcing plate, and an adhesive layer. The flexible circuit board defines a first opening, a first connecting portion, and a second connecting portion. The image sensor includes a photosensitive area exposed in the first opening and a connection area electrically coupled with the first connecting portion through a conductive body. The reinforcing plate and the image sensor are located on a same side of the flexible circuit board. The adhesive layer covers edges of the image sensor and couples the image sensor to the flexible circuit board. A lens module and an electronic device comprising the packaging structure are also disclosed.

### FIELD

The subject matter herein generally relates to imaging, specifically a packaging structure, a lens module including the packaging structure, and an electronic device including the lens module.

### BACKGROUND

Generally, a lens module includes a ceramic substrate with wires, a circuit board, and an image sensor. The ceramic substrate is electrically connected with the circuit board and defines an opening to accommodate the image sensor. The ceramic substrate is delicate and very brittle, and during assembly, chips and dust from the ceramic substrate may fall onto a surface of the image sensor, affecting image quality of the image sensor, and reducing the product yield.

### BRIEF DESCRIPTION OF THE DRAWINGS

Implementations of the present technology will now be described, by way of embodiment, with reference to the attached figures.

FIG. 1 is a schematic view of a packaging structure according to an embodiment of the present disclosure.

FIG. 2 is a schematic view of a packaging structure according to another embodiment of the present disclosure.

FIG. 3 is a schematic view of a packaging structure according to yet another embodiment of the present disclosure.

FIG. 4 is a schematic view of a lens module according to an embodiment of the present disclosure.

FIG. 5 is a schematic view of an electronic device according to an embodiment of the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. Some methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising,” when utilized, means “including, but not necessarily limited to”; it specifically indicates open-ended inclusion or membership in the so-described combination, group, series, and the like.

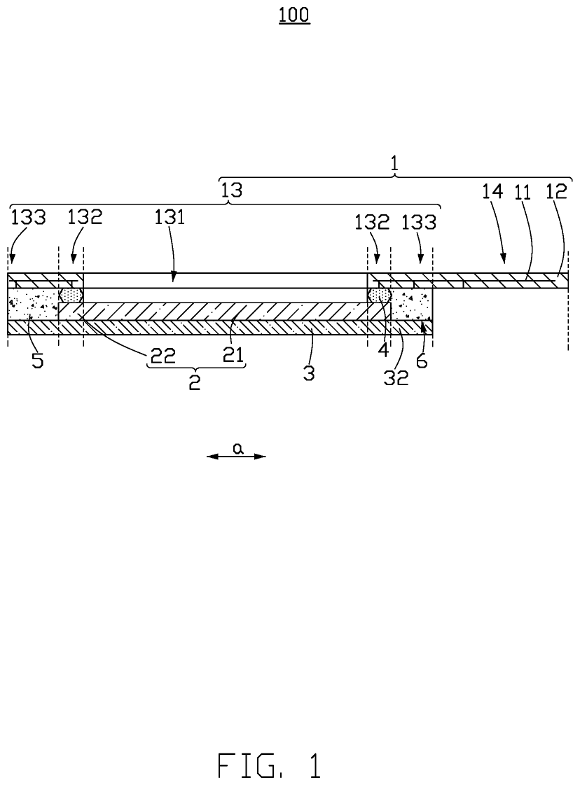

Referring to FIG. 1, an embodiment of a packaging structure 100 is illustrated. The packaging structure 100 includes a flexible circuit board 1, an image sensor 2, a reinforcing plate 3, a conductive body 4, and an adhesive layer 5. The flexible circuit board 1 defines a first opening 131, a first connecting portion 132 surrounding the first opening 131, and a second connecting portion 133 surrounding and coupled with the first connecting portion 132. The image sensor 2 includes a photosensitive area 21 and a connection area 22 surrounding the photosensitive area 21. The connection area 22 is electrically coupled with the first connecting portion 132 through the conductive body 4. The photosensitive area 21 is exposed in the first opening 131. The reinforcing plate 3 and the image sensor 2 are located on a same side of the flexible circuit board 1. Specifically, the reinforcing plate 3 is arranged on a surface of the image sensor 2 facing away from the flexible circuit board 1. Along extending direction a of the flexible circuit board 1, the reinforcing plate 3 extends beyond edges of the image sensor 2, thereby forming an accommodation chamber 6 between the reinforcing plate 3 and the second connecting portion 133. The adhesive layer 5 is arranged in the accommodation chamber 6 and extends between the connection area 22 and the first connecting portion 132. The adhesive layer 5 thus covers edges of the image sensor 2 and couples the image sensor 2, the flexible circuit board 1, and the reinforcing plate 3.

The flexible circuit board 1 includes a dielectric layer 11 and a circuit layer 11 distributed in the dielectric layer 11. The circuit layer 11 is used for conducting electricity.

The flexible circuit board 1 includes a first flexible board 13 and a second flexible board 14 coupled with each other. The first flexible board 13 is electrically coupled with the image sensor 2. The second flexible board 14 is electrically coupled to an external circuit. The first opening 131, the first connecting portion 132, and the second connecting portion 133 are all defined on the first flexible board 13.

The first opening 131 penetrates the first flexible board 13 along a direction perpendicular to the extending direction a of the flexible circuit board 1. A shape of the first opening 131 can be arranged as actually required, for example, the first opening 131 can be circular, square, or rectangular.

The first connecting portion 132 encloses the first opening 131. A portion of the circuit layer 12 located at the first connecting portion 132 is exposed outside the dielectric layer 11, for electric connections with the conductive body 4. The first flexible board 13 is thus electrically coupled with the image sensor 2.

The photosensitive area 21 corresponds to the first opening 131. That is, the photosensitive area 21 is exposed in the first opening 131. The connection area 22 corresponds to the first connecting portion 132. The connection area 22 is electrically coupled with the first connecting portion 132 through the conductive body 4. The conductive body 4 is electrically coupled with the circuit layer 12. In this embodiment, the conductive body 4 may be gold balls, tin balls, silver paste, etc.

The reinforcing plate 3 is attached to the surface of the image sensor 2 through another adhesive layer 7. The reinforcing plate 3 provides complete physical protection for reverse side of the image sensor 2, protecting the image sensor 2 from damage during assembly of a lens module, and so improving the product yield. The adhesive layer 7 may be a double-sided adhesive.

Along the extending direction a of the flexible circuit board 1, the reinforcing plate 3 extends beyond edges of the image sensor 2, that is, a size of the reinforcing plate 3 is slightly larger than a size of the image sensor 2, so that the weak and delicate edges of the image sensor 2 are protected by an edge portion 32 of the reinforcing plate 3 extending beyond the edges of image sensor 2. The accommodation chamber 6 is formed between the edge portion 32 and the second connecting portion 133. The accommodation chamber 6 contains the adhesive layer 5. The reinforcing plate 3 and the adhesive layer 5 together cover the image sensor 2, forming structure giving complete protection, and protecting the image sensor 2 from damage. The adhesive layer 5 in the accommodation chamber 6 also covers the conductive body 4, thereby improving strength and stability of connection between the image sensor 2 and the flexible circuit board 1. The reinforcing plate 3 is arranged on the surface of the image sensor 2, and the flexible circuit board 1 is coupled with the image sensor 2 only through the conductive body 4, so having little or no impact on flatness of the flexible circuit board 1 and not causing warping of the flexible circuit board 1.

The reinforcing plate 3 is made of metal. The reinforcing plate 3 made of metal also functions as electromagnetic shielding and is an element in better heat dissipation efficiency of the image sensor 2.

A thin metal plate can be used as the reinforcing plate 3 and is combined with the adhesive layer 5 to protect the image sensor, reducing a total thickness of the packaging structure 100.

The adhesive layer 5 infills gaps between the first connecting portion 132, the reinforcing plate 3, the connection area 22, and the conductive body 4. The adhesive layer 5 bonds together the flexible circuit board 1, the image sensor 2, the reinforcing plate 3, and the conductive 4, so that the reinforcing plate 3 and the adhesive layer 5 form an integrated protective structure covering the image sensor 2 and the conductive body 4. The image sensor 2 is protected against damage, and the strength and stability of connection between the image sensor 2 and the flexible circuit board 1 is improved. The adhesive layer 5 can be a UV (ultraviolet) curing adhesive or a thermosetting adhesive. In this embodiment, the adhesive layer 5 is a thermosetting adhesive.

An assembly process of the packaging structure 100 includes the following steps.

Step S11, the flexible circuit board 1 is provided, the flexible circuit board 1 having the first opening 131, the first connecting portion 132 surrounding the first opening 131, and the second connecting portion 133 surrounding and coupled with the first connecting portion 132.

Step S12, the image sensor 2 is provided, the image sensor 2 including the photosensitive area 21 and the connection area 22 surrounding the photosensitive area 21. The connection area 22 is electrically coupled with the first connecting portion 132 through the conductive body 4, and the photosensitive area 21 is exposed in the first opening 131.

Step S13, the reinforcing plate 3 is attached to the surface of the image sensor 2 facing away from the flexible circuit board 1, the reinforcing plate 3 extends beyond edges of the image sensor 2 along the extending direction a of the flexible circuit board 1, forming the accommodation chamber 6 between the reinforcing plate 3 and the second connecting portion 133.

Step S14, the accommodation chamber 6 is filled with a thermosetting adhesive, the thermosetting adhesive reaching between connection area 22 and the first connecting portion 132, then the thermosetting adhesive is cured to form the adhesive layer 5, thus obtaining the packaging structure 100.

In other embodiments, the reinforcing plate 3 can be attached to the surface of the image sensor 2 first, and then the image sensor 2 attached with the reinforcing plate 3 can be fixed on the flexible circuit board 1. In this way, the reinforcing plate 3 is attached to the image sensor 2 first, providing protection for the image sensor 2, thereby avoiding damage to the edges and surfaces of the image sensor 2 when the image sensor 2 is directly fixed on the flexible circuit board 1.

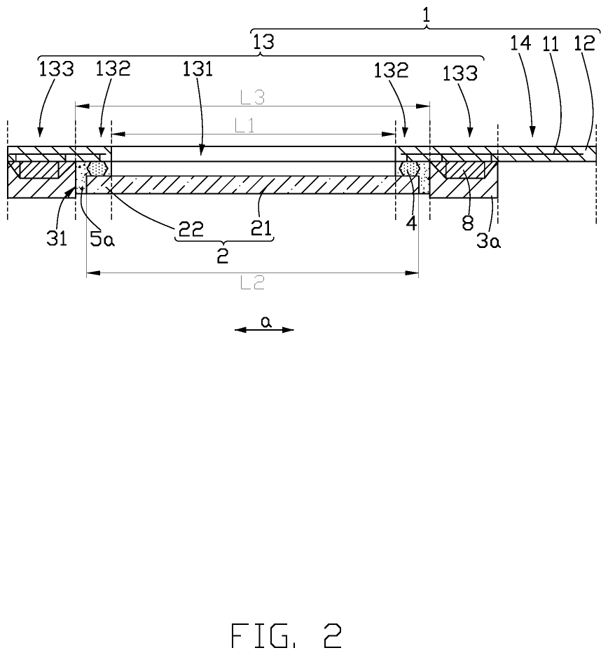

Referring to FIG. 2, an embodiment of a packaging structure 200 is illustrated. The differences between the packaging structure 200 and the packaging structure 100 are that the packaging structure 200 includes a reinforcing plate 3a and an adhesive layer 5a. The reinforcing plate 3a is arranged on a surface of the second connecting portion 133 and defines a second opening 31 communicating with the first opening 131 and containing the image sensor 2. The connection area 22 is electrically coupled with the first connecting portion 132 through the conductive body 4, the photosensitive area 21 is exposed in the first opening 131, and the surface of the image sensor 2 facing away from the flexible circuit board 1 is lower than a surface of the reinforcing plate 3a facing away from the flexible circuit board 1, so that the image sensor 2 recesses into the reinforcing plate 3a. The adhesive layer 5a is arranged between the reinforcing plate 3a and the connection area 22 and extends between the connection area 22 and the first connecting portion 132.

The surface of the reinforcing plate 3a facing away from the flexible circuit board 1 extends slightly beyond the surface of the image sensor 2 facing away from the flexible circuit board 1, which protects the edges of the image sensor 2 and reduces the risk of damage to the edges. In addition, the reinforcement board 3a being arranged on the surface of the second connecting portion 133 increases the strength of the flexible circuit board 1, maintains the flatness of the flexible circuit board 1, and improves yield of the packaging structure 200.

Along the extending direction a of the flexible circuit board 1, a size L1 of the first opening 131 is smaller than a size L2 of the image sensor 2, and the size L2 is smaller than a size L3 of the second opening 31.

The reinforcing plate 3a is coupled with the flexible circuit board 1 and provides insulation. The reinforcing plate 3a is further coupled with the dielectric layer 11. Specifically, the reinforcing plate 3a is made of plastic and is formed on the surface of the second connecting portion 133 by injection molding, so the reinforcing plate 3a is not easily broken away and will not produce debris, reducing the risk of poor imaging and damage to the surface of the image sensor 2 caused by debris.

Referring to FIG. 2, the packaging structure 200 further includes a passive element 8, which is embedded in the reinforcing plate 3a and is electrically coupled with the second connecting portion 133. The passive element 8 is encapsulated in the reinforcing plate 3a before the image sensor 2 is soldered onto the flexible circuit board 1, the possibility of tin solder contamination on the passive element 8 falling on the image sensor 2 is avoided, the risk of damage to the surface of the image sensor 2 is reduced, and the yield of the packaging structure 200 is improved.

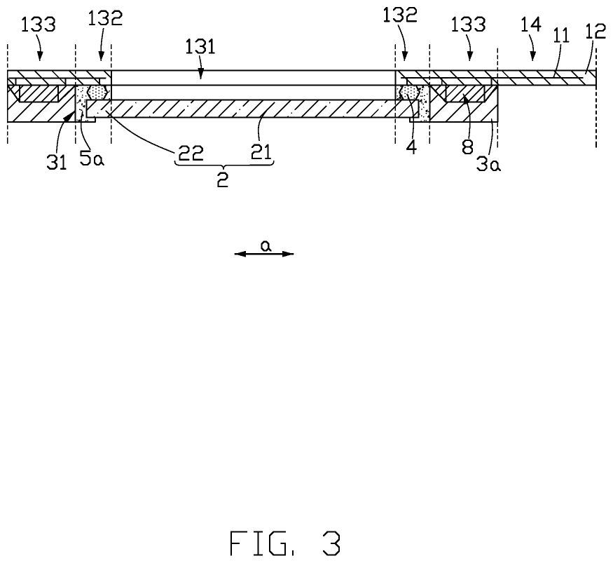

Referring to FIG. 3, the adhesive layer 5a further reaches to a surface of the connection area 22 facing away from the flexible circuit board 1, so that the adhesive layer 5a encapsulates edge portion of the image sensor 2, protecting the edges of the image sensor 2 from damage.

An assembly process of the packaging structure 200 includes the following steps.

Step S21, the flexible circuit board 1 is provided, the flexible circuit board 1 having the first opening 131, the first connecting portion 132 surrounding the first opening 131, and the second connecting portion 133 surrounding and coupled with the first connecting portion 132.

Step S22, the passive element 8 is soldered on the surface of the second connecting portion 133.

Step S23, the reinforcing plate 3a is formed on the surface of the second connecting portion 133 with the passive element 8 by injection molding, the reinforcing plate 3a encapsulating the passive element 8 and defining the second opening 31 communicating with the first opening 131.

Step S24, the image sensor 2 is placed in the second opening 31, the image sensor 2, the reinforcing plate 3a, and the flexible circuit board 1 are spaced from each other, and the photosensitive area 21 of the image sensor 2 is exposed in the first opening 131. The connection area 22 of the image sensor 2 is electrically coupled with the first connecting portion 132 through the conductive body 4, and the surface of the image sensor 2 facing away from the flexible circuit board 1 is lower than the surface of the reinforcing plate 3a facing away from the flexible circuit board 1.

Step S25, the thermosetting adhesive infills a gap between the reinforcing plate 3a and the connection area 22, the thermosetting adhesive reaching between the connection area 22 and the first connecting portion 132, then the thermosetting adhesive is cured to form the adhesive layer 5a, thus obtaining the packaging structure 200.

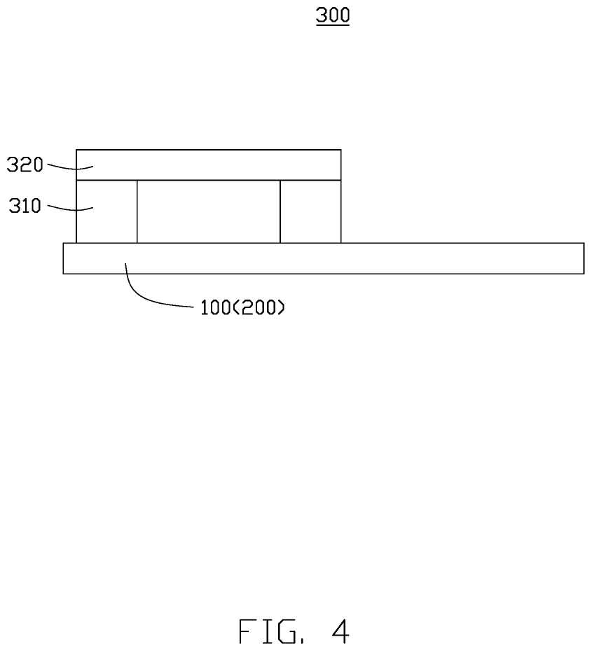

Referring to FIGS. 1, 2, and 4, a lens module 300 is illustrated. The lens module 300 includes the packaging structure 100 (200), a lens holder 310, and a lens assembly 320. The lens holder 310 is arranged on a surface of the packaging structure 100 (200) facing away from the reinforcing plate 3 (3a) and is coupled with the first flexible board 13, the second flexible board 14 extending beyond the lens holder 310. The lens assembly 320 is arranged on an end of the lens holder 310 facing away from the packaging structure 100 (200).

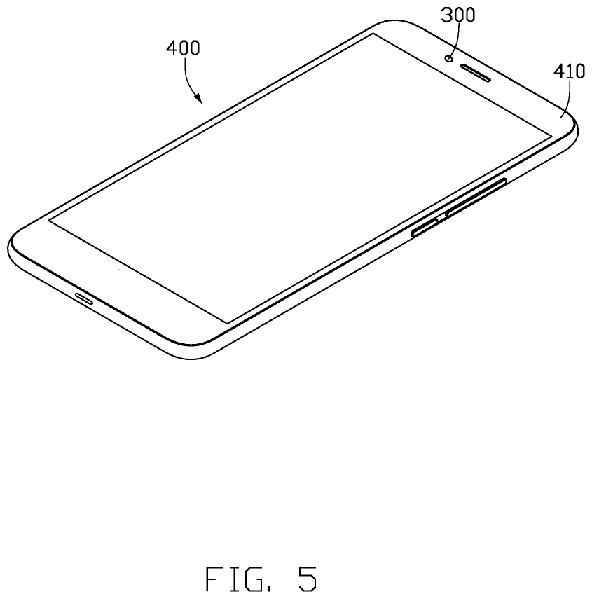

Referring to FIG. 5, an embodiment of an electronic device 400 is illustrated. The electronic device 400 includes a housing 410 and the lens module 300. The electronic device 200 can be any electronic device having image-capturing functions, such as mobile phones, wearable devices, computer devices, vehicles, or monitoring devices. In an alternative embodiment, the electronic device 200 is a mobile phone.

While the present disclosure has been described with reference to particular embodiments, the description is illustrative of the disclosure and is not to be construed as limiting the disclosure. Those of ordinary skill in the art can make various modifications to the embodiments without departing from the scope of the disclosure as defined by the appended claims.

What is claimed is:

1. A packaging structure comprising:
a flexible circuit board comprising a first opening, a first connecting portion surrounding the first opening, and a second connecting portion surrounding and coupled with the first connecting portion;
an image sensor comprising a photosensitive area and a connection area surrounding the photosensitive area, the connection area being electrically coupled with the first connecting portion through a conductive body, the photosensitive area being exposed by the first opening;
a reinforcing plate, wherein the reinforcing plate and the image sensor are located on a same side of the flexible circuit board; and
an adhesive layer covering edges of the image sensor and coupling the image sensor, the reinforcing plate, and the flexible circuit board.

2. The packaging structure of claim 1, wherein the reinforcing plate is arranged on a surface of the image sensor facing away from the flexible circuit board and extends beyond the edges of the image sensor, an accommodation chamber is formed between the second connecting portion and the reinforcing plate, and the adhesive layer is received in the accommodation chamber and extends to the connection area of the image sensor and the first connecting portion of the flexible circuit board.

3. The packaging structure of claim 2, wherein the reinforcing plate is attached to the image sensor by another adhesive layer.

4. The packaging structure of claim 2, wherein a material of the reinforcing plate is metal.

5. The packaging structure of claim 1, wherein the reinforcing plate is arranged on a surface of the second connecting portion and defines a second opening communicating with the first opening, the image sensor is arranged in the second opening and recesses into the reinforcing plate, and the adhesive layer is arranged between the reinforcing plate and the connection area and extends to the connection area and the first connecting portion.

6. The packaging structure of claim 5, wherein a size of the first opening is smaller than a size of the image sensor, and the size of the image sensor is smaller than a size of the second opening.

7. The packaging structure of claim 5, wherein a material of the reinforcing plate is plastic.

8. The packaging structure of claim 7, further comprising a passive element embedded in the reinforcing plate and electrically coupled with the second connecting portion.

9. The packaging structure of claim 5, wherein the adhesive layer further extends to a surface of the connection area facing away from the flexible circuit board.

10. A lens module comprising:
a packaging structure; and
a lens assembly arranged on the packaging structure;
wherein the packaging structure comprises:
a flexible circuit board comprising a first opening, a first connecting portion surrounding the first opening, and a second connecting portion surrounding and coupled with the first connecting portion;
an image sensor comprising a photosensitive area and a connection area surrounding the photosensitive area, the connection area being electrically coupled with the first connecting portion through a conductive body, the photosensitive area being exposed by the first opening;
a reinforcing plate, wherein the reinforcing plate and the image sensor are located on a same side of the flexible circuit board; and
an adhesive layer covering edges of the image sensor and coupling the image sensor, the reinforcing plate, and the flexible circuit board.

11. The lens module of claim 10, wherein the reinforcing plate is arranged on a surface of the image sensor facing away from the flexible circuit board and extends beyond the edges of the image sensor, an accommodation chamber is formed between the second connecting portion and the reinforcing plate, and the adhesive layer is received in the accommodation chamber and extends to the connection area of the image sensor and the first connecting portion of the flexible circuit board.

12. The lens module of claim 11, wherein a material of the reinforcing plate is metal.

13. The lens module of claim 11, the reinforcing plate is attached to the image sensor by another adhesive layer.

14. The lens module of claim 10, wherein the reinforcing plate is arranged on a surface of the second connecting portion and defines a second opening communicating with the first opening, the image sensor is arranged in the second opening and recesses into the reinforcing plate, and the adhesive layer is arranged between the reinforcing plate and the connection area and extends to the connection area and the first connecting portion.

15. The lens module of claim 14, wherein a size of the first opening is smaller than a size of the image sensor, and the size of the image sensor is smaller than a size of the second opening.

16. The lens module of claim 14, wherein a material of the reinforcing plate is plastic.

17. The lens module of claim 16, wherein the packaging structure further comprises a passive element embedded in the reinforcing plate and electrically coupled with the second connecting portion.

18. The lens module of claim 14, wherein the adhesive layer further extends to a surface of the connection area facing away from the flexible circuit board.

19. An electronic device comprising a lens module, the lens module comprising:
a packaging structure; and
a lens assembly arranged on the packaging structure;
wherein the packaging structure comprises:
a flexible circuit board comprising a first opening, a first connecting portion surrounding the first opening, and a second connecting portion surrounding and coupled with the first connecting portion;
an image sensor comprising a photosensitive area and a connection area surrounding the photosensitive area, the connection area being electrically coupled with the first connecting portion through a conductive body, the photosensitive area being exposed by the first opening;
a reinforcing plate, wherein the reinforcing plate and the image sensor are located on a same side of the flexible circuit board; and
an adhesive layer covering edges of the image sensor and coupling the image sensor, the reinforcing plate, and the flexible circuit board.

20. The electronic device of claim 19, wherein the reinforcing plate is arranged on a surface of the image sensor facing away from the flexible circuit board and extends beyond the edges of the image sensor, an accommodation chamber is formed between the second connecting portion and the reinforcing plate, and the adhesive layer is received in the accommodation chamber and extends to the connection area of the image sensor and the first connecting portion of the flexible circuit board.
